(19) United States
(12) Patent Application Publication
(10) Pub. No.: US 2019/0056486 A1
(43) Pub. Date: Feb. 21, 2019

(54) FILTER DEVICE FOR FILTERING A SUPPLY VOLTAGE OF AN ULTRASONIC SENSOR OF A MOTOR VEHICLE, ULTRASONIC SENSOR DEVICE AND MOTOR VEHICLE

(71) Applicant: VALEO Schalter und Sensoren GmbH, Bietigheim-Bissingen (DE)

(72) Inventor: Erich Mok, Bietigheim-Bissingen (DE)

(73) Assignee: VALEO Schalter und Sensoren GmbH, Bietigheim-Bissingen (DE)

(21) Appl. No.: 16/079,199

(22) PCT Filed: Jan. 30, 2017
(86) PCT No.: PCT/EP2017/051899

§ 371 Date: Aug. 23, 2018

(30) Foreign Application Priority Data
Feb. 29, 2016 (DE) 10 2016 103 514.9

(51) Int. Cl. G01S 7/524; G01S 15/93; B06B 1/02; H03H 11/04

(52) U.S. Cl. CPC G01S 7/524; G01S 15/931; B06B 2201/30; H03H 11/04; G01S 2015/938; B06B 1/0215

(57) ABSTRACT

The invention relates to a filter device (9) for filtering a supply voltage (Ub) of an ultrasonic sensor (10) of a motor vehicle (1), wherein the filter device (9) is electrically connectable on the input side to a voltage source (8), which provides the supply voltage (Ub), and on the output side to the ultrasonic sensor (10) and wherein the filter device (9) comprises a low-pass filter with a resistor (R1) and a capacitor (C1), wherein the filter device (9) comprises a diode (D2), which is connected in parallel with the resistor (R1).

The present invention relates to a filter device for filtering a supply voltage of an ultrasonic sensor of a motor vehicle, wherein the filter is electrically connectable on the input side to a voltage source which provides the supply voltage, and on the output side to the ultrasonic sensor and wherein the filter device comprises a low-pass filter, which has a resistor and a capacitor. In addition, the present invention relates to an ultrasonic sensor device with an ultrasonic sensor and such a filter device. The present invention also relates to a motor vehicle having such an ultrasonic sensor device.

In this case the topic of interest is focused in particular on ultrasonic sensors for motor vehicles. Such ultrasonic sensors can be arranged, for example, on a bumper of the vehicle and are used to detect objects in the surroundings of the motor vehicle. In order to be able to detect the objects, an ultrasonic signal is emitted using the ultrasonic sensor during a transmit phase. To this end a diaphragm of the ultrasonic sensor is excited into vibration using an appropriate transducer element, such as a piezoelectric element. In order to be able to operate the transducer element during the transmit phase, relatively high electric currents are required. In a subsequent evaluation phase, the ultrasonic signal reflected from the object is received again using the ultrasonic sensor. During the evaluation phase, the transducer element is not excited. In this case, the ultrasonic sensor is operated with a relatively small evaluation current, or operating current.

Ultrasonic sensors are commonly supplied with electrical energy by a voltage source of the motor vehicle. To be able to filter the supply voltage provided by the voltage source, filter devices are normally used which have a low-pass or RC element. The filter device therefore comprises a resistor and a capacitor, wherein depending on the dimensions of the resistor and capacitor, a specific time constant and a resulting cutoff frequency are obtained, above which the filter develops a significant attenuation. Due to space restrictions it is often not possible to use capacitors that have a relatively high capacitance. If a relatively low cutoff frequency is then to be achieved, resistors with a high resistance value must be used. In particular during the transmit phase, in which high electric currents are supplied, this leads to a significant voltage drop across the resistor.

In this connection, EP 0 623 395 B1 describes a circuit arrangement for attenuating an ultrasonic transducer. The circuit arrangement can be used for an ultrasonic transducer which is designed both as a transmitter and as a receiver. The circuit arrangement has a generator, which is designed to control the activation voltage for the ultrasonic transducer in such a way that the amplitude of the emitted ultrasonic transducer signal corresponding to the control voltage decays according to a specified envelope curve for the decay time. Furthermore, the generator has means, as a result of which the specified envelope curve initially decays to a non-zero voltage value within a period of time and then the voltage value of the envelope curve is almost constant for a specific period of time. These means can have, for example, an RC element connected as a low-pass filter.

The object of the present invention is to indicate a solution as to how a filter device for an ultrasonic sensor of the above-mentioned type can be operated more effectively in a simple way.

This object is achieved according to the invention by means of a filter device, by an ultrasonic sensor device and by a motor vehicle having the features in accordance with the respective independent claims. Advantageous extensions of the present invention are the subject matter of the dependent claims, the description and the figures.

A filter device according to the invention is used to filter a supply voltage of an ultrasonic sensor of a motor vehicle. The filter device can be electrically connected on the input side to the voltage source, which provides the supply voltage, and on the output side to the ultrasonic sensor. The filter device also comprises a low-pass filter, which has a resistor and a capacitor. It is provided according to the invention that the filter device comprises a diode, which is connected in parallel with the resistor.

The filter device can be used for an ultrasonic sensor of a motor vehicle. Such an ultrasonic sensor can be arranged, for example, on a bumper of the motor vehicle. This ultrasonic sensor can have a diaphragm which is made from aluminium, for example, and can have a cup-shaped design. In addition, the ultrasonic sensor can have a transducer element, for example a piezoelectric element, with which the diaphragm or a base of the diaphragm can be excited into mechanical vibration. In order to excite the transducer element, during a transmit phase of the ultrasonic sensor a relatively high transmission current is required. In a subsequent evaluation phase, the transducer element is no longer excited. In this case, the ultrasonic signal reflected from the object is received, strikes the diaphragm and excites it into vibration. These vibrations of the membrane can then be detected with the transducer element. During the evaluation phase, the ultrasonic sensor is supplied with a relatively low evaluation current. This is used, for example, to supply a processing device, in particular a microprocessor, of the ultrasonic sensor.

The supply voltage is provided using a voltage source of the motor vehicle. The voltage source can also be used to provide an electric current. The voltage source can be, for example, a battery or an accumulator. The voltage source can also be part of an on-board network of the motor vehicle. In order to filter the supply voltage which is provided by the voltage source, the filter device is used. In particular, the filter device is designed to filter out high-frequency signal components or interference from the supply voltage. To this end, the filter device comprises a low-pass filter, which has a resistor and a capacitor connected in parallel with the resistor. The filter device can have input terminals that can be electrically connected to the voltage source of the motor vehicle. The resistance of the low-pass filter is connected in series with one of the input terminals and the capacitor of the low-pass filter is connected in parallel with the input terminals. In addition, the filter device can have output terminals that can be electrically connected to the ultrasonic sensor.

It is then provided according to the invention that the filter device also comprises a diode, which is connected in parallel with the resistor. By connecting the diode in parallel with the resistor, particularly in the case of the high transmission currents, the voltage drop can be limited to the forward voltage, or the diode forward voltage or diode clamping voltage. This forward voltage of the diode can be, for example, 0.5 V or 0.7 V. Thus, the filter device can be operated more efficiently, in particular during the transmit phase of the ultrasonic sensor.

Preferably, the diode and/or the resistor are dimensioned in such a way that the diode conducts if a specified transmission current flows through the filter device during a transmit phase of the ultrasonic sensor. During the transmit phase of the ultrasonic sensor, in which the ultrasound signal is emitted, the transmission current is provided, which can be, for example, 1 A. In principle, it can also be provided that a pulsed transmission current is provided during the transmit phase. In this case, the diode and/or the resistance are dimensioned in such a way that this transmission current causes a voltage drop across the diode which causes it to conduct. This means that the resistance value of the resistor and/or the forward voltage of the diode are selected such that the diode conducts if the transmission current flows through the filter device. Thus, the voltage drop is limited to the forward voltage of the diode. The resistance of the low-pass filter or RC element is therefore in a sense bypassed by the diode. The low-pass filter has almost no filter effect any longer, but this is often not required in the transmit phase of the ultrasonic sensor.

In a further embodiment, the diode and/or the resistor are dimensioned in such a way that the diode blocks if a specified evaluation current flows through the filter device during an evaluation phase of the ultrasonic sensor. During the evaluation phase of the ultrasonic sensor a relatively low evaluation current is required to operate the ultrasonic sensor, which can be a few mA, for example. This evaluation current is used, for example, to operate a processing device or a microprocessor of the ultrasonic sensor. In particular during the evaluation phase, it is necessary that interference is filtered out of the power supply voltage. In this case, the diode and/or the resistance are dimensioned in such a way that with the evaluation current that flows through the filter device, the diode does not conduct. This means that the evaluation current substantially flows through the resistor of the low-pass filter. In this case, the diode, which is connected in parallel with the resistor, is therefore highly resistive. This means that the time constant of the low-pass filter is defined by the resistance. Therefore, the supply voltage during the evaluation phase can be reliably filtered.

In total therefore, a filter device is provided, which adapts dynamically to the operating state—in other words, the transmit phase or the evaluation phase—of the ultrasonic sensor. This is achieved using the diode, which is connected in parallel to the resistor. This means the filter device can be provided in a space-saving and cost-effective manner.

In a further embodiment the filter device comprises an additional diode connected in series with the resistor. The additional diode, which is electrically connected in series with the resistor, can provide a reverse polarity protection. This can prevent damage to the ultrasonic sensor if it is connected incorrectly.

In a further embodiment, the filter device has at least one additional capacitor, which is connected in parallel with the capacitor of the low-pass filter. For example, it can be provided that the filter device has two additional capacitors, which are connected in parallel with the capacitor of the low-pass filter. These additional capacitors are used in particular as energy stores for a processor device, or the microprocessor of the ultrasonic sensor. This can be used to ensure that the processor device is supplied with the required voltage.

An ultrasonic sensor device according to the invention for a motor vehicle comprises an ultrasonic sensor and a filter device according to the invention. It can also be provided that the input terminals of the filter device are electrically connected to the voltage source of the motor vehicle, such as a battery or an on-board network. The output terminals of the filter device can also be electrically connected to the ultrasonic sensor.

A motor vehicle according to the invention comprises at least one ultrasonic sensor device according to the invention. It can also be provided that the motor vehicle has a plurality of ultrasonic sensor devices. In this case the respective ultrasonic sensors of the ultrasonic sensor devices can be distributed on the motor vehicle in the area of the bumpers. In particular, the motor vehicle is designed as a passenger car.

The preferred embodiments presented in relation to the filter device according to the invention and their advantages apply mutatis mutandis both to the ultrasonic sensor device according to the invention and to the motor vehicle according to the invention.

Additional features of the invention arise from the claims, the Figures and the description of the Figures. The features and feature combinations cited in the description above, and the features and feature combinations cited in the description of the Figures below and/or shown in the Figures alone are applicable not only in the respective combination indicated but also in other combinations or in isolation, without departing from the scope of the invention. Therefore, such embodiments of the invention are also to be considered as comprised and disclosed as are not explicitly shown or explained in the Figures, but which emerge from and can be generated from the embodiments described by separate feature combinations. Embodiments and combinations of features are also to be regarded as disclosed, which therefore do not have all features of an originally formulated independent claim.

The invention will now be described in greater detail based on preferred exemplary embodiments and by reference to the attached drawings.

These show:

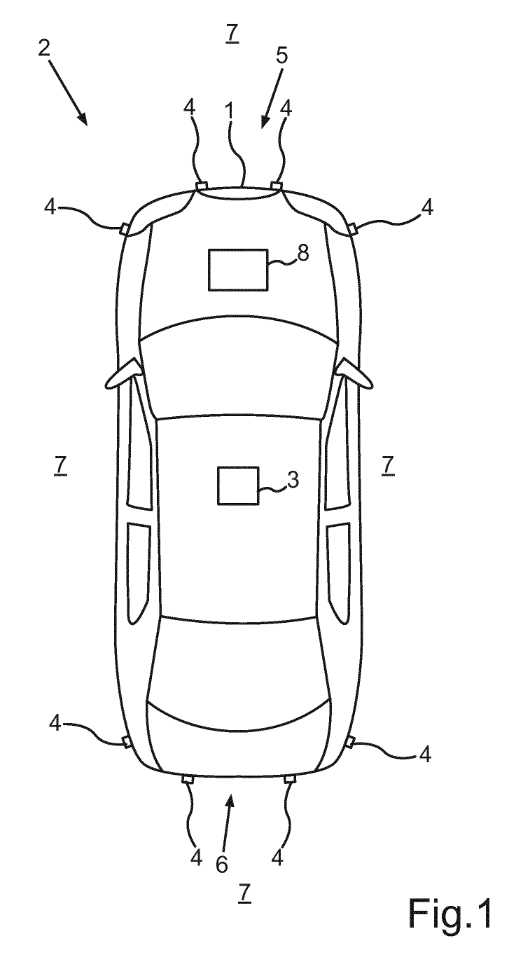

FIG. 1 a motor vehicle in accordance with one embodiment of the present invention, which has a plurality of ultrasonic sensor devices;

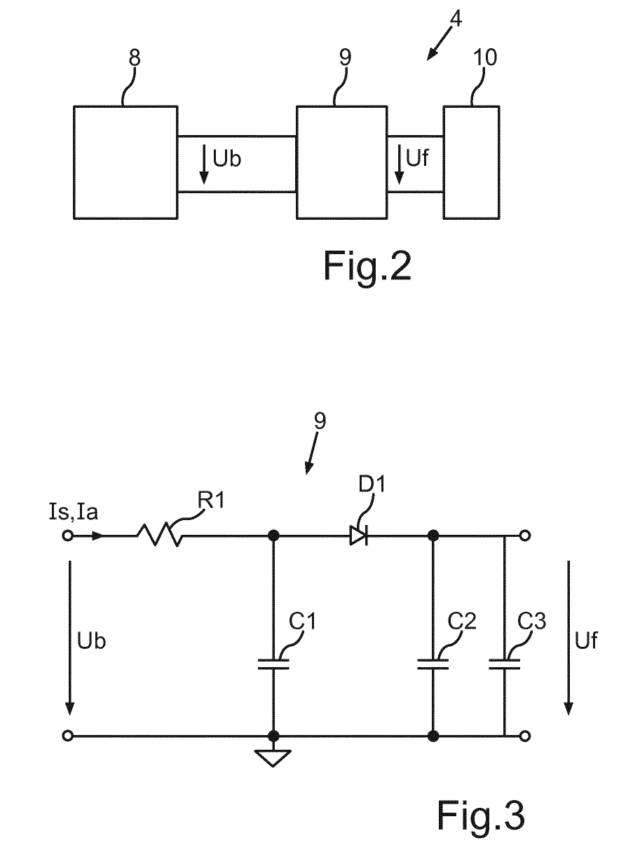

FIG. 2 a schematic representation of an ultrasonic sensor device that is connected to a voltage source of the motor vehicle;

FIG. 3 a circuit of a filter device of the ultrasonic sensor device in accordance with the prior art; and

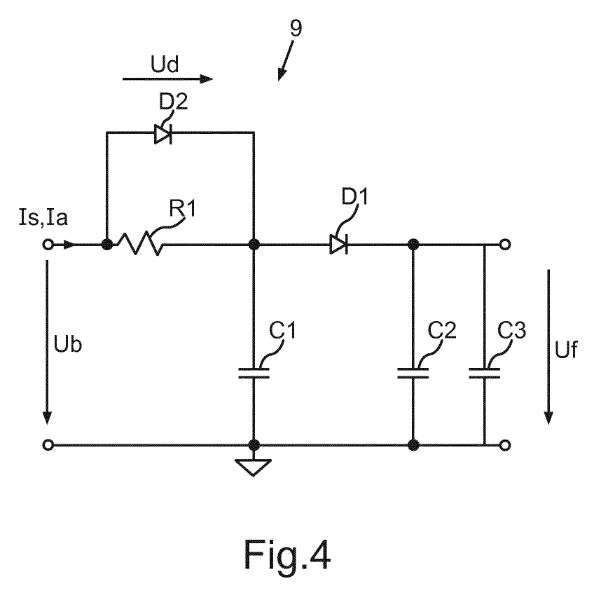

FIG. 4 a circuit of a filter device in accordance with an embodiment of the present invention.

In the Figures, identical and functionally equivalent elements are indicated by identical reference marks.

FIG. 1 shows a motor vehicle 1 according to one embodiment of the present invention in a plan view. The motor vehicle 1 in the present case is designed as a passenger car. The motor vehicle 1 comprises a driver assistance system 2, which in turn comprises a control device 3. The driver assistance system 2 additionally comprises at least one ultrasonic sensor device 4. In the present case, the driver assistance system 2 comprises eight ultrasonic sensor devices 4, wherein four ultrasonic sensor devices 4 are arranged in a front section 5 of the motor vehicle 1 and four ultrasonic sensor devices 4 in a rear section 6 of the motor vehicle 1. As explained in more detail below, each of the ultrasonic sensor devices 4 comprises one ultrasonic sensor 10, with which objects in a surrounding area 7 of the motor vehicle can be detected. In this regard, the ultrasonic sensors 10 can be arranged on the bumpers of the motor vehicle 1. The respective ultrasonic sensor devices 4 can be controlled by means of the control device 3.

The motor vehicle 1 also comprises a voltage source 8, which is provided for example by an electrical energy store of the motor vehicle 1. Such an electrical energy store of the motor vehicle 1 can be, for example, a battery or an on-board power supply of the motor vehicle 1. The respective ultrasonic sensor devices 4 are electrically connected to the voltage source 8. The ultrasonic sensor devices 4, or the ultrasonic sensors 10, are supplied with electrical energy by the voltage source 8 when in operation.

FIG. 2 shows a schematic representation of an ultrasonic sensor device 4, which is electrically connected to the voltage source 8. The voltage source 8 provides a supply voltage Ub. The ultrasonic sensor device 4 comprises a filter device 9, which is used to filter this supply voltage Ub. The filter device 9 is connected on the input side to the voltage source 8. On the output side the filter device 9 is connected to the ultrasonic sensor 10. At the output of the filter device 9 the filtered supply voltage Uf is present. This filtered supply voltage Uf is used to supply the ultrasonic sensor 10.

The ultrasonic sensor 10 is used, on the one hand, to emit an ultrasonic signal during a transmit phase. In a subsequent evaluation phase the ultrasonic signal reflected from the object is received again by means of the ultrasonic sensor 10. The ultrasonic sensor 10 comprises a diaphragm, which is stimulated into mechanical vibration with the aid of a corresponding transducer element. In order to operate the transducer element, during the transmit phase a transmission current is provided, which can be, for example, 1 A. In the subsequent evaluation phase, the transducer element is not operated. Here, with the voltage source 8 an evaluation current Ia is provided, with which the ultrasonic sensor 10 and, in particular, a processing unit or microprocessor of the ultrasonic sensor 10 is operated. During the evaluation phase, by means of the transducer element the reflected ultrasound signal, which strikes the membrane and excites it into vibration, is detected. In particular during the evaluation phase of the ultrasonic sensor 10, it is necessary that interference is filtered out of the supply voltage Ub to be able to detect the reflected ultrasound signals reliably.

FIG. 3 shows a circuit of a filter device 9 according to the prior art. The circuit has the input terminals at which the supply voltage Ub of the voltage source 8 is applied. In addition, the filter device 9 comprises a low-pass filter or RC element. This low-pass filter comprises a resistor R1 and a capacitor C1. The capacitor C1 is connected in parallel with the input terminals and in parallel with the resistor R1. Depending on the resistance value of the resistor R1 and the capacitance of the capacitor C1, a specific time constant τ=R1*C1 is obtained. The cutoff frequency fc of the low-pass filter is given by: fc=½*π*τ.

The capacitance of the capacitor C1 cannot be selected to be arbitrarily large, due to space limitations. For example, the capacitance of the capacitor C1 can be 100 nF. If the resistor R1 has a resistance of 100 Ohm, a time constant of 6.8 ms and a cutoff frequency of 24 Hz are obtained. If a transmission current Is of 1 A flows through the resistor during the transmit phase, this results in a voltage drop on the resistor R1 of 100 V.

In order to prevent such a significant voltage drop across the resistor R1, the resistance value of the resistor R1 could be chosen to be very small. For example, if the resistance value of the resistor R1 were to be 0.5 Ohm, this results in a time constant of 10 μs and a cutoff frequency of 16 kHz. For a transmission current Is of 1 A this would result in a voltage drop of 0.5 V. In this case a small voltage drop is obtained across the resistor R1. However, this means in turn that the cutoff frequency fc of the low-pass filter increases very rapidly for a constant capacitance of the capacitor C1, so that the effect of the filter significantly decreases. The filter device 9 also comprises a diode D1, which is connected in series with the resistor R1. This diode D1 is used for reverse polarity protection. In addition, the filter device comprises the additional capacitors C2 and C3. The capacitances of the capacitors C2 and C3 can each be 10 μF. These capacitors C2 and C3 are used as energy stores for the processor device, or microprocessor of the ultrasonic sensor 10.

FIG. 4 shows a circuit of a filter device 9 according to one embodiment of the invention. In comparison to the circuit according to FIG. 3, the filter device 9 additionally comprises a diode D2, which is connected in parallel with the resistor R1. By connecting the diode D2 in parallel with the resistor R1, when the high transmission current Is is applied the voltage drop is limited to the forward voltage Ud or the diode clamping voltage. The forward voltage Ud of the diode D2 can be, for example, 0.5 V. If the transmission current is provided during the transmit phase, the low-pass filter has almost no effect, but this is not required during the transmit phase of the ultrasonic sensor 10. During the evaluation phase, in which the evaluation current Ia flows through the low-pass filter, the diode D2 has a high resistance, so that the filter time constant is now defined by the resistor R1. This considerably higher value results in a much better filter effect.

The resistor R1 must be dimensioned in such a way that at the evaluation current Ia, or the operating current, the diode D2 has a high resistance. The following must apply: R1*Ia<Ud. If the resistor R1 has a resistance of 100 Ohm, for a capacitance of the capacitor C1 of 100 nF this results in a cutoff frequency of 24 Hz. If a transmission current is provided which is equal to 1 A, this results in a voltage drop on the diode D2 equal to the forward voltage Ud, which can be, for example, 0.5 V. For the evaluation phase the evaluation current is subject to the constraint Ia<Ud/R1. Even if a forward voltage Ud of 0.4 V is assumed, a permissible current of 4 mA is obtained for the evaluation current Ia or operating current. At such a current, the full effect of the low-pass filter or the RC element can be realized. At the same time, during the transmit phase the transmission current Is is provided without an excessive voltage drop. It can also be provided that a pulsed current Is is supplied during the transmit phase. With this circuit or this filter device, high pulse currents are thus possible for the transmit phase while in the subsequent evaluation phase with the low evaluation current Ia the advantageous filter effect of the low-pass filter can still be achieved. Therefore, the filter device 9 can be used overall to provide a dynamic supply voltage filter.

1. A filter device for filtering a supply voltage (Ub) of an ultrasonic sensor of a motor vehicle, wherein:
the filter device is electrically connectable on an input side to a voltage source, which provides the supply voltage (Ub), and on an output side to the ultrasonic sensor,
the filter device comprising a low-pass filter with a resistor (R1) and a capacitor (C1), wherein the filter device comprises a diode (D2) connected in parallel with the resistor (R1).

2. The filter device according to claim 1, wherein the diode (D2) and/or the resistor (R1) are dimensioned in such a way that the diode (D2) conducts when a specified transmission current (Is) flows through the filter device during a transmit phase of the ultrasonic sensor.

3. The filter device according to claim 1, wherein the diode (D2) and/or the resistor (R1) are dimensioned in such a way that the diode (D2) does not conduct when a specified evaluation current (Ia) flows through the filter device during an evaluation phase of the ultrasonic sensor.

4. The filter device according to claim 3, wherein the diode (D2) and/or the resistor (R1) are dimensioned in such a way that a resistance value of the resistor (R1) is less than a quotient of a forward voltage (Ud) of the diode (D2) and the evaluation current (Ia).

5. The filter device according to claim 1, wherein the filter device comprises an additional diode (D1), which is connected in series with the resistor (R1) of the low-pass filter.

6. The filter device according to claim 1, wherein the filter device has at least one additional capacitor, which is connected in parallel with the capacitor of the low-pass filter.

7. An ultrasonic sensor device for a motor vehicle comprising an ultrasonic sensor; and a filter device according to claim 1.

8. A motor vehicle having at least one ultrasonic sensor device according to claim 7.
